(19) United States
(12) Patent Application Publication
(10) Pub. No.: US 2025/0253170 A1
(43) Pub. Date: Aug. 7, 2025

(54) HEAT TREATMENT APPARATUS FOR HEATING SEMICONDUCTOR WAFER BY LIGHT IRRADIATION

(71) Applicant: SCREEN Holdings Co., Ltd., Kyoto (JP)

(72) Inventors: Shogo SHIGEMASU, Kyoto-shi (JP); Nobuo EDAMOTO, Kyoto-shi (JP); Takahiro YAMADA, Kyoto-shi (JP)

(21) Appl. No.: 18/988,794

(22) Filed: Dec. 19, 2024

(30) Foreign Application Priority Data
Feb. 6, 2024 (JP) 2024-016160

(51) Int. Cl. H01L 21/67; H01S 5/02315; H01S 5/0233; H10H 20/85; H10H 20/857

(52) U.S. Cl. CPC H01L 21/67115; H01S 5/02315; H01S 5/0233; H10H 20/8508; H10H 20/857; H01L 21/67248

(57) ABSTRACT

A flash heating part including multiple flash lamps is provided over a chamber for receiving a semiconductor wafer therein, and an auxiliary heating part is provided under the chamber. The auxiliary heating part is provided with multiple chips each including a semiconductor light emitting element. A pattern of an electrically conductive material is formed on a substrate made of aluminum nitride, and a plating layer of gold is formed on the pattern. A connection surface of each of the chips faces downward, and electrodes provided on the lower surface thereof are connected to electrodes on the pattern side by bumps. The bumps are hidden behind the chips as seen from the flash lamps, and are prevented from being damaged by flash irradiation.

### BACKGROUND OF THE INVENTION

### Field of the Invention

The present invention relates to a heat treatment apparatus which irradiates a semiconductor wafer with light to heat the semiconductor wafer. In particular, the present invention relates to a flash lamp annealer which irradiates a semiconductor wafer with a flash of light.

### Description of the Background Art

In the process of manufacturing a semiconductor device, attention has been given to flash lamp annealing (FLA) which heats a semiconductor wafer in an extremely short time. The flash lamp annealing is a heat treatment technique in which xenon flash lamps (the term “flash lamp” as used hereinafter refers to a “xenon flash lamp”) are used to irradiate a surface of a semiconductor wafer with a flash of light, thereby raising the temperature of only the surface of the semiconductor wafer in an extremely short time (several milliseconds or less).

The xenon flash lamps have a spectral distribution of radiation ranging from ultraviolet to near-infrared regions. The wavelength of light emitted from the xenon flash lamps is shorter than that of light emitted from conventional halogen lamps, and approximately coincides with a fundamental absorption band of a silicon semiconductor wafer. Thus, when a semiconductor wafer is irradiated with a flash of light emitted from the xenon flash lamps, the temperature of the semiconductor wafer can be raised rapidly, with only a small amount of light transmitted through the semiconductor wafer. Also, it has turned out that flash irradiation, that is, the irradiation of a semiconductor wafer with a flash of light in an extremely short time of several milliseconds or less allows a selective temperature rise only near the surface of the semiconductor wafer.

Such flash lamp annealing is used for processes that require heating in an extremely short time, e.g. typically for the activation of impurities implanted in a semiconductor wafer. The irradiation of the surface of the semiconductor wafer implanted with impurities by an ion implantation process with a flash of light emitted from the flash lamps allows the temperature rise in the surface of the semiconductor wafer to an activation temperature only for an extremely short time, thereby achieving only the activation of the impurities without deep diffusion of the impurities.

A typical example of an apparatus for performing such flash lamp annealing includes a heat treatment apparatus in which flash lamps are provided over a chamber that receives a semiconductor wafer therein and halogen lamps are provided under the chamber (as disclosed in U.S. Patent Application Publication No. 2011/0262115). In the apparatus disclosed in U.S. Patent Application Publication No. 2011/0262115, a semiconductor wafer is preheated by light irradiation from the halogen lamps, and thereafter a front surface of the semiconductor wafer is irradiated with flashes of light from the flash lamps. The preheating is performed by the halogen lamps because only the flash irradiation makes it difficult for the front surface of the semiconductor wafer to reach a target temperature.

Unfortunately, the halogen lamps mainly emit infrared light with a relatively long wavelength. Semiconductor wafers of silicon have a low spectral absorptance of infrared light with a longer wavelength of not less than 1 μm in a low temperature range of 500° C. or below. In other words, semiconductor wafers at 500° C. or below do not absorb much infrared light emitted from the halogen lamps. This results in inefficient heating of the semiconductor wafers in the initial stage of the preheating.

To solve such a problem, Japanese Patent Application Laid-Open No. 2022-166682 proposes a technique of preheating a semiconductor wafer with the use of LED (Light Emitting Diode) lamps in place of the halogen lamps. LED lamps which emit light with a wavelength of not greater than 1 μm are capable of efficiently heating even relatively low-temperature semiconductor wafers.

As disclosed in Japanese Patent Application Laid-Open No. 2022-166682, semiconductor light emitting elements such as LED lamps are mounted on a substrate. Typically, a chip including a semiconductor light emitting element is mounted on a substrate by wire bonding. The wire bonding refers to a method of connecting a chip to electrodes provided on a substrate with wires made of gold or the like.

However, if a substrate on which chips are mounted by wire bonding is provided in the flash lamp annealer, the substrate is irradiated with direct or reflected light emitted from the flash lamps during heat treatment. This gives rise to apprehension that damages to the wires result in breaks in the wires. As a result, the semiconductor light emitting elements no longer emit light.

The substrate on which the semiconductor light emitting elements are mounted has been made of copper or the like with good thermal conductivity in consideration of heat dissipation from the semiconductor light emitting elements. Typically, an insulative layer made of epoxy resin or the like has been provided on the copper substrate, and a copper wiring pattern has been formed on the insulative layer.

However, when such a substrate is irradiated with flashes of light from the flash lamps, there have been cases in which the insulative layer made of resin gets burned. This has led to the deterioration of the semiconductor light emitting elements, and there has been a danger that the burning adheres to the semiconductor light emitting elements to result in a decrease in the amount of light.

### SUMMARY

The present invention is intended for a heat treatment apparatus for irradiating a semiconductor wafer with light to heat the semiconductor wafer.

According to one aspect of the present invention, the heat treatment apparatus comprises: a chamber for receiving a semiconductor wafer therein; a holder for holding the semiconductor wafer in the chamber; an auxiliary light source provided on one side of the chamber and for irradiating the semiconductor wafer held by the holder with light, the auxiliary light source including a substrate and a chip including a semiconductor light emitting element; and a flash lamp provided on the other side of the chamber and for irradiating the semiconductor wafer preheated by the auxiliary light source with a flash of light, wherein an electrode provided on a second surface of the chip opposite from a first surface thereof opposed to the flash lamp is connected to the substrate through a bump.

The bump is hidden behind the chip as seen from the flash lamp. This prevents damages to the auxiliary light source due to flash irradiation.

Preferably, the substrate is made of an inorganic insulating material.

The substrate does not get burned during the flash irradiation. This prevents damages to the auxiliary light source due to the flash irradiation.

According to another aspect of the present invention, the heat treatment apparatus comprises: a chamber for receiving a semiconductor wafer therein; a holder for holding the semiconductor wafer in the chamber; an auxiliary light source provided on one side of the chamber and for irradiating the semiconductor wafer held by the holder with light, the auxiliary light source including an insulative substrate made of an inorganic material and a chip including a semiconductor light emitting element; and a flash lamp provided on the other side of the chamber and for irradiating the semiconductor wafer preheated by the auxiliary light source with a flash of light.

The insulative substrate does not get burned during the flash irradiation. This prevents damages to the auxiliary light source due to the flash irradiation.

It is therefore an object of the present invention to prevent damages to an auxiliary light source due to flash irradiation.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a longitudinal sectional view showing a configuration of a heat treatment apparatus according to the present invention;

FIG. 2 is a perspective view showing the entire external appearance of a holder;

FIG. 3 is a plan view of a susceptor;

FIG. 4 is a sectional view of the susceptor;

FIG. 5 is a plan view of a transfer mechanism;

FIG. 6 is a side view of the transfer mechanism;

FIG. 7 is a plan view of the inside of an auxiliary heating part as seen from above;

FIG. 8 is a plan view of a chip group; and

FIG. 9 is a view showing a chip mounting method.

### DESCRIPTION OF THE PREFERRED EMBODIMENTS

A preferred embodiment according to the present invention will now be described in detail with reference to the drawings. In the following description, expressions indicating relative or absolute positional relationships (e.g., “in one direction”, “along one direction”, “parallel”, “orthogonal”, “center”, “concentric”, and “coaxial”) shall represent not only the exact positional relationships but also a state in which the angle or distance is relatively displaced to the extent that tolerances or similar functions are obtained, unless otherwise specified. Also, expressions indicating equal states (e.g., “identical”, “equal”, and “homogeneous”) shall represent not only a state of quantitative exact equality but also a state in which there are differences that provide tolerances or similar functions, unless otherwise specified. Also, expressions indicating shapes (e.g., “circular”, “rectangular”, and “cylindrical”) shall represent not only the geometrically exact shapes but also shapes to the extent that the same level of effectiveness is obtained, unless otherwise specified, and may have unevenness or chamfers. Also, an expression such as “comprising”, “equipped with”, “provided with”, “including”, or “having” a component is not an exclusive expression that excludes the presence of other components. Also, the expression “at least one of A, B, and C” includes “A only”, “B only”, “C only”, “any two of A, B, and C”, and “all of A, B, and C”.

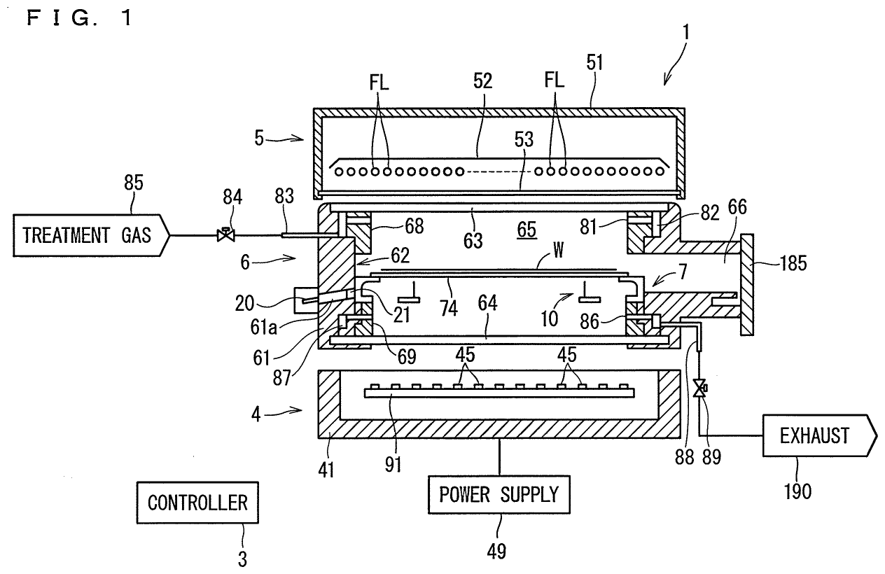

FIG. 1 is a longitudinal sectional view showing a configuration of a heat treatment apparatus 1 according to the present invention. The heat treatment apparatus 1 of FIG. 1 is a flash lamp annealer for irradiating a disk-shaped semiconductor wafer W of silicon (Si) with flashes of light to heat the semiconductor wafer W. The size of the semiconductor wafer W to be treated is not particularly limited. For example, the semiconductor wafer W to be treated has a diameter of 300 mm and 450 mm. It should be noted that the dimensions of components and the number of components are shown in exaggeration or in simplified form, as appropriate, in FIG. 1 and the subsequent figures for the sake of easier understanding.

The heat treatment apparatus 1 includes a chamber 6 for receiving a semiconductor wafer W therein, a flash heating part 5 including a plurality of built-in flash lamps FL, and an auxiliary heating part 4 in which a plurality of chips 45 are provided on a substrate 91. The flash heating part 5 is provided over the chamber 6, and the auxiliary heating part 4 is provided under the chamber 6. The heat treatment apparatus 1 further includes a holder 7 provided inside the chamber 6 and for holding a semiconductor wafer W in a horizontal attitude, and a transfer mechanism 10 provided inside the chamber 6 and for transferring a semiconductor wafer W between the holder 7 and the outside of the heat treatment apparatus 1. The heat treatment apparatus 1 further includes a controller 3 for controlling operating mechanisms provided in the auxiliary heating part 4, the flash heating part 5, and the chamber 6 to cause the operating mechanisms to heat-treat a semiconductor wafer W.

The chamber 6 is configured such that upper and lower chamber windows 63 and 64 made of quartz are mounted to the top and bottom, respectively, of a tubular chamber side portion 61. The chamber side portion 61 has a generally tubular shape having an open top and an open bottom. The upper chamber window 63 is mounted to block the top opening of the chamber side portion 61, and the lower chamber window 64 is mounted to block the bottom opening thereof. The upper chamber window 63 forming the ceiling of the chamber 6 is a disk-shaped member made of quartz, and serves as a quartz window that transmits flashes of light emitted from the flash heating part 5 therethrough into the chamber 6. The lower chamber window 64 forming the floor of the chamber 6 is also a disk-shaped member made of quartz, and serves as a quartz window that transmits light emitted from the auxiliary heating part 4 therethrough into the chamber 6.

An upper reflective ring 68 is mounted to an upper portion of the inner wall surface of the chamber side portion 61, and a lower reflective ring 69 is mounted to a lower portion thereof. Both of the upper and lower reflective rings 68 and 69 are in the form of an annular ring. The upper reflective ring 68 is mounted by being inserted downwardly from the top of the chamber side portion 61. The lower reflective ring 69, on the other hand, is mounted by being inserted upwardly from the bottom of the chamber side portion 61 and fastened with screws not shown. In other words, the upper and lower reflective rings 68 and 69 are removably mounted to the chamber side portion 61. An interior space of the chamber 6, i.e. a space surrounded by the upper chamber window 63, the lower chamber window 64, the chamber side portion 61, and the upper and lower reflective rings 68 and 69, is defined as a heat treatment space 65.

A recessed portion 62 is defined in the inner wall surface of the chamber 6 by mounting the upper and lower reflective rings 68 and 69 to the chamber side portion 61. Specifically, the recessed portion 62 is defined which is surrounded by a middle portion of the inner wall surface of the chamber side portion 61 where the reflective rings 68 and 69 are not mounted, a lower end surface of the upper reflective ring 68, and an upper end surface of the lower reflective ring 69. The recessed portion 62 is provided in the form of a horizontal annular ring in the inner wall surface of the chamber 6, and surrounds the holder 7 which holds a semiconductor wafer W. The chamber side portion 61 and the upper and lower reflective rings 68 and 69 are made of a metal material (e.g., stainless steel) with high strength and high heat resistance.

The chamber side portion 61 is provided with a transport opening (throat) 66 for the transport of a semiconductor wafer W therethrough into and out of the chamber 6. The transport opening 66 is openable and closable by a gate valve 185. The transport opening 66 is connected in communication with an outer peripheral surface of the recessed portion 62. Thus, when the transport opening 66 is opened by the gate valve 185, a semiconductor wafer W is allowed to be transported through the transport opening 66 and the recessed portion 62 into and out of the heat treatment space 65. When the transport opening 66 is closed by the gate valve 185, the heat treatment space 65 in the chamber 6 is an enclosed space.

The chamber side portion 61 is further provided with a through hole 61a bored therein. A radiation thermometer 20 is mounted in a location of an outer wall surface of the chamber side portion 61 where the through hole 61a is provided. The through hole 61a is a cylindrical hole for directing infrared light emitted from a lower surface of a semiconductor wafer W held by a susceptor 74 to be described later therethrough to the radiation thermometer 20. The through hole 61a is inclined with respect to a horizontal direction so that a longitudinal axis (an axis extending in a direction in which the through hole 61a extends through the chamber side portion 61) of the through hole 61a intersects a main surface of the semiconductor wafer W held by the susceptor 74. Thus, the radiation thermometer 20 is provided obliquely below the susceptor 74. A transparent window 21 made of barium fluoride material transparent to infrared light in a wavelength range measurable by the radiation thermometer 20 is mounted to an end portion of the through hole 61a which faces the heat treatment space 65.

At least one gas supply opening 81 for supplying a treatment gas therethrough into the heat treatment space 65 is provided in an upper portion of the inner wall of the chamber 6. The gas supply opening 81 is provided above the recessed portion 62, and may be provided in the upper reflective ring 68. The gas supply opening 81 is connected in communication with a gas supply pipe 83 through a buffer space 82 provided in the form of an annular ring inside the side wall of the chamber 6. The gas supply pipe 83 is connected to a treatment gas supply source 85. A valve 84 is interposed in the gas supply pipe 83. When the valve 84 is opened, the treatment gas is fed from the treatment gas supply source 85 to the buffer space 82. The treatment gas flowing in the buffer space 82 flows in a spreading manner within the buffer space 82 which is lower in fluid resistance than the gas supply opening 81, and is supplied through the gas supply opening 81 into the heat treatment space 65. Examples of the treatment gas usable herein include inert gases such as nitrogen gas (N₂), reactive gases such as hydrogen (H₂) and ammonia (NH₃), and mixtures of these gases (although nitrogen gas is used in the present preferred embodiment).

At least one gas exhaust opening 86 for exhausting a gas from the heat treatment space 65 is provided in a lower portion of the inner wall of the chamber 6. The gas exhaust opening 86 is provided below the recessed portion 62, and may be provided in the lower reflective ring 69. The gas exhaust opening 86 is connected in communication with a gas exhaust pipe 88 through a buffer space 87 provided in the form of an annular ring inside the side wall of the chamber 6. The gas exhaust pipe 88 is connected to an exhaust part 190. A valve 89 is interposed in the gas exhaust pipe 88. When the valve 89 is opened, the gas in the heat treatment space 65 is exhausted through the gas exhaust opening 86 and the buffer space 87 to the gas exhaust pipe 88. The at least one gas supply opening 81 and the at least one gas exhaust opening 86 may include a plurality of gas supply openings 81 and a plurality of gas exhaust openings 86, respectively, arranged in a circumferential direction of the chamber 6, and may be in the form of slits. The treatment gas supply source 85 and the exhaust part 190 may be mechanisms provided in the heat treatment apparatus 1 or be utility systems in a factory in which the heat treatment apparatus 1 is installed.

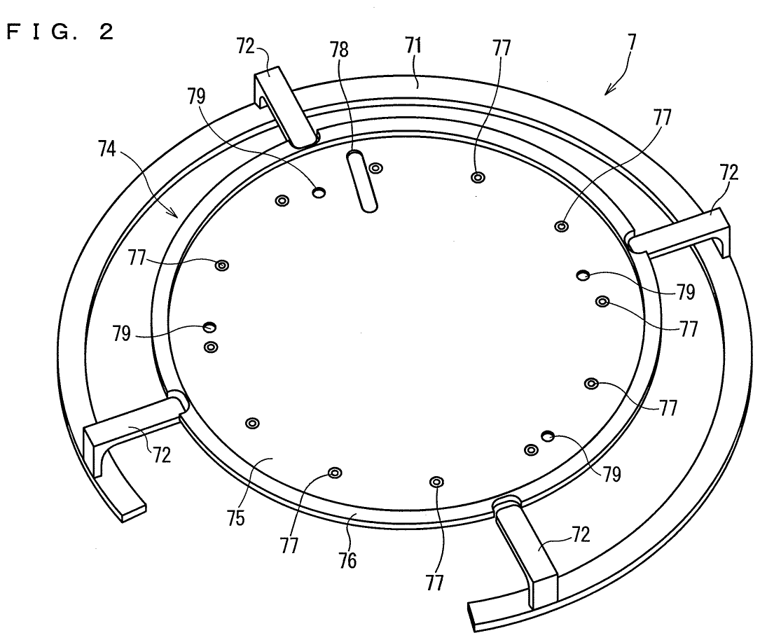

FIG. 2 is a perspective view showing the entire external appearance of the holder 7. The holder 7 includes a base ring 71, coupling portions 72, and the susceptor 74. The base ring 71, the coupling portions 72, and the susceptor 74 are all made of quartz. In other words, the whole of the holder 7 is made of quartz.

The base ring 71 is a quartz member having an arcuate shape obtained by removing a portion from an annular shape. This removed portion is provided to prevent interference between transfer arms 11 of the transfer mechanism 10 to be described later and the base ring 71. The base ring 71 is supported by the wall surface of the chamber 6 by being placed on the bottom surface of the recessed portion 62 (with reference to FIG. 1). The multiple coupling portions 72 (in the present preferred embodiment, four coupling portions 72) are mounted upright on the upper surface of the base ring 71 and arranged in a circumferential direction of the annular shape thereof. The coupling portions 72 are quartz members, and are rigidly secured to the base ring 71 by welding.

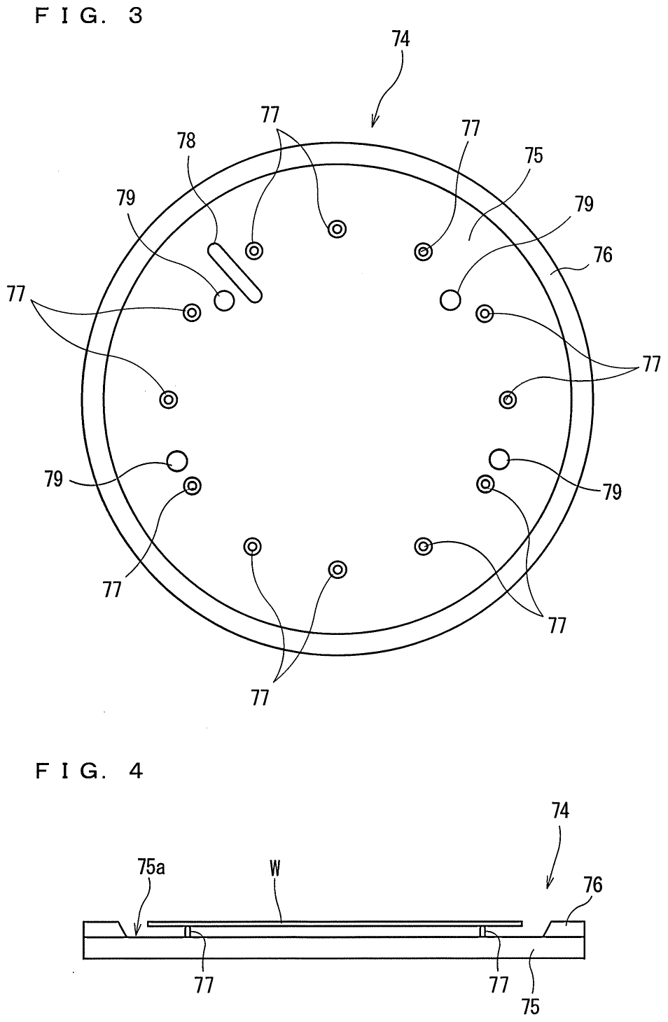

The susceptor 74 is supported by the four coupling portions 72 provided on the base ring 71. FIG. 3 is a plan view of the susceptor 74. FIG. 4 is a sectional view of the susceptor 74. The susceptor 74 includes a holding plate 75, a guide ring 76, and a plurality of substrate support pins 77. The holding plate 75 is a generally circular planar member made of quartz. The diameter of the holding plate 75 is greater than that of a semiconductor wafer W. In other words, the holding plate 75 has a size, as seen in plan view, greater than that of the semiconductor wafer W.

The guide ring 76 is provided on a peripheral portion of the upper surface of the holding plate 75. The guide ring 76 is an annular member having an inner diameter greater than the diameter of the semiconductor wafer W. For example, when the diameter of the semiconductor wafer W is 300 mm, the inner diameter of the guide ring 76 is 320 mm. The inner periphery of the guide ring 76 is in the form of a tapered surface which becomes wider in an upward direction from the holding plate 75. The guide ring 76 is made of quartz similar to that of the holding plate 75. The guide ring 76 may be welded to the upper surface of the holding plate 75 or fixed to the holding plate 75 with separately machined pins and the like. Alternatively, the holding plate 75 and the guide ring 76 may be machined as an integral member.

A region of the upper surface of the holding plate 75 which is inside the guide ring 76 serves as a planar holding surface 75a for holding the semiconductor wafer W. The substrate support pins 77 are provided upright on the holding surface 75a of the holding plate 75. In the present preferred embodiment, a total of 12 substrate support pins 77 are spaced at intervals of 30 degrees along the circumference of a circle concentric with the outer circumference of the holding surface 75a (the inner circumference of the guide ring 76). The diameter of the circle on which the 12 substrate support pins 77 are disposed (the distance between opposed ones of the substrate support pins 77) is smaller than the diameter of the semiconductor wafer W, and is 270 to 280 mm (in the present preferred embodiment, 270 mm) when the diameter of the semiconductor wafer W is 300 mm. Each of the substrate support pins 77 is made of quartz. The substrate support pins 77 may be provided by welding on the upper surface of the holding plate 75 or machined integrally with the holding plate 75.

Referring again to FIG. 2, the four coupling portions 72 provided upright on the base ring 71 and the peripheral portion of the holding plate 75 of the susceptor 74 are rigidly secured to each other by welding. In other words, the susceptor 74 and the base ring 71 are fixedly coupled to each other with the coupling portions 72. The base ring 71 of such a holder 7 is supported by the wall surface of the chamber 6, whereby the holder 7 is mounted to the chamber 6. With the holder 7 mounted to the chamber 6, the holding plate 75 of the susceptor 74 assumes a horizontal attitude (an attitude such that the normal to the holding plate 75 coincides with a vertical direction). In other words, the holding surface 75a of the holding plate 75 becomes a horizontal surface.

A semiconductor wafer W transported into the chamber 6 is placed and held in a horizontal attitude on the susceptor 74 of the holder 7 mounted to the chamber 6. At this time, the semiconductor wafer W is supported by the 12 substrate support pins 77 provided upright on the holding plate 75, and is held by the susceptor 74. More strictly speaking, the 12 substrate support pins 77 have respective upper end portions coming in contact with the lower surface of the semiconductor wafer W to support the semiconductor wafer W. The semiconductor wafer W is supported in a horizontal attitude by the 12 substrate support pins 77 because the 12 substrate support pins 77 have a uniform height (distance from the upper ends of the substrate support pins 77 to the holding surface 75a of the holding plate 75).

The semiconductor wafer W supported by the substrate support pins 77 is spaced a predetermined distance apart from the holding surface 75a of the holding plate 75. The thickness of the guide ring 76 is greater than the height of the substrate support pins 77. Thus, the guide ring 76 prevents the horizontal misregistration of the semiconductor wafer W supported by the substrate support pins 77.

As shown in FIGS. 2 and 3, an opening 78 is provided in the holding plate 75 of the susceptor 74 so as to extend vertically through the holding plate 75 of the susceptor 74. The opening 78 is provided for the radiation thermometer 20 to receive radiation (infrared light) emitted from the lower surface of the semiconductor wafer W. Specifically, the radiation thermometer 20 receives the radiation emitted from the lower surface of the semiconductor wafer W through the opening 78 and the transparent window 21 mounted to the through hole 61a in the chamber side portion 61 to measure the temperature of the semiconductor wafer W. Further, the holding plate 75 of the susceptor 74 further includes four through holes 79 bored therein and designed so that lift pins 12 of the transfer mechanism 10 to be described later pass through the through holes 79, respectively, to transfer a semiconductor wafer W.

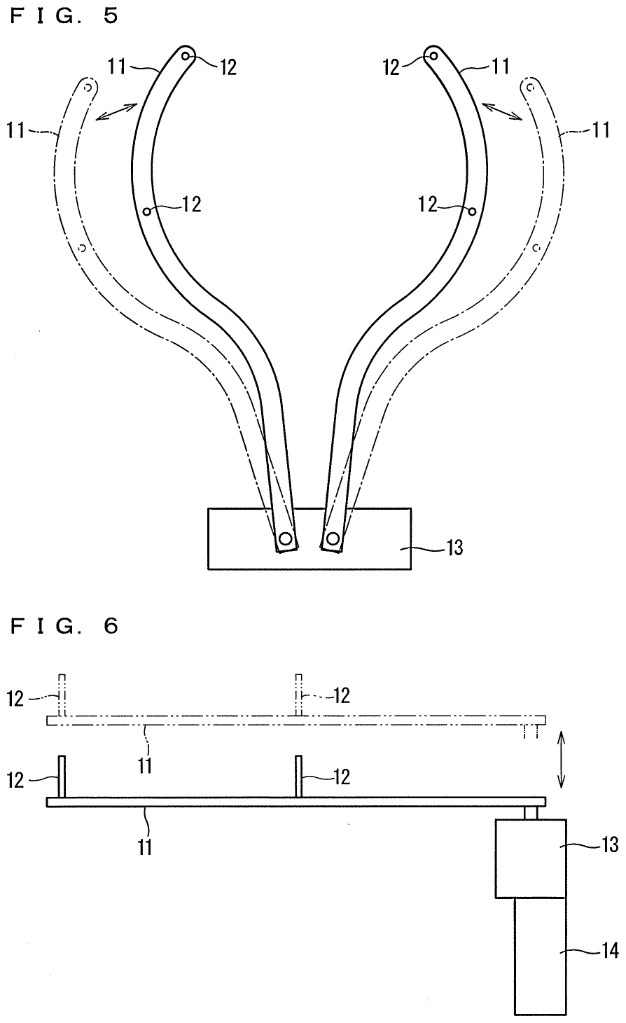

FIG. 5 is a plan view of the transfer mechanism 10. FIG. 6 is a side view of the transfer mechanism 10. The transfer mechanism 10 includes the two transfer arms 11. The transfer arms 11 are of an arcuate configuration extending substantially along the annular recessed portion 62. Each of the transfer arms 11 includes the two lift pins 12 mounted upright thereon. The transfer arms 11 and the lift pins 12 are made of quartz. The transfer arms 11 are pivotable by a horizontal movement mechanism 13. The horizontal movement mechanism 13 moves the pair of transfer arms 11 horizontally between a transfer operation position (a position indicated by solid lines in FIG. 5) in which a semiconductor wafer W is transferred to and from the holder 7 and a retracted position (a position indicated by dash-double-dot lines in FIG. 5) in which the transfer arms 11 do not overlap the semiconductor wafer W held by the holder 7 as seen in plan view. The horizontal movement mechanism 13 may be of the type which causes individual motors to pivot the transfer arms 11 respectively or of the type which uses a linkage mechanism to cause a single motor to pivot the pair of transfer arms 11 in cooperative relation.

The transfer arms 11 are moved upwardly and downwardly together with the horizontal movement mechanism 13 by an elevating mechanism 14. As the elevating mechanism 14 moves up the pair of transfer arms 11 in their transfer operation position, the four lift pins 12 in total pass through the respective four through holes 79 (with reference to FIGS. 2 and 3) bored in the susceptor 74, so that the upper ends of the lift pins 12 protrude from the upper surface of the susceptor 74. On the other hand, as the elevating mechanism 14 moves down the pair of transfer arms 11 in their transfer operation position to take the lift pins 12 out of the respective through holes 79 and the horizontal movement mechanism 13 moves the pair of transfer arms 11 so as to open the transfer arms 11, the transfer arms 11 move to their retracted position. The retracted position of the pair of transfer arms 11 is immediately over the base ring 71 of the holder 7. The retracted position of the transfer arms 11 is inside the recessed portion 62 because the base ring 71 is placed on the bottom surface of the recessed portion 62. An exhaust mechanism not shown is also provided near the location where the drivers (the horizontal movement mechanism 13 and the elevating mechanism 14) of the transfer mechanism 10 are provided, and is configured to exhaust an atmosphere around the drivers of the transfer mechanism 10 to the outside of the chamber 6.

Referring again to FIG. 1, the flash heating part 5 provided over the chamber 6 includes an enclosure 51, a light source provided inside the enclosure 51 and including the multiple (in the present preferred embodiment, 30) xenon flash lamps FL, and a reflector 52 provided inside the enclosure 51 so as to cover the light source from above. The flash heating part 5 further includes a lamp light radiation window 53 mounted to the bottom of the enclosure 51. The lamp light radiation window 53 forming the floor of the flash heating part 5 is a plate-like quartz window made of quartz. The flash heating part 5 is provided over the chamber 6, whereby the lamp light radiation window 53 is opposed to the upper chamber window 63. The flash lamps FL direct flashes of light from over the chamber 6 through the lamp light radiation window 53 and the upper chamber window 63 toward the heat treatment space 65.

The flash lamps FL, each of which is a rod-shaped lamp having an elongated cylindrical shape, are arranged in a plane so that the longitudinal directions of the respective flash lamps FL are in parallel with each other along a main surface of a semiconductor wafer W held by the holder 7 (that is, in a horizontal direction). Thus, a plane defined by the arrangement of the flash lamps FL is also a horizontal plane. A region in which the flash lamps FL are arranged has a size, as seen in plan view, greater than that of the semiconductor wafer W.

Each of the xenon flash lamps FL includes a cylindrical glass tube (discharge tube) containing xenon gas sealed therein and having positive and negative electrodes provided on opposite ends thereof and connected to a capacitor, and a trigger electrode attached to the outer peripheral surface of the glass tube. Because the xenon gas is electrically insulative, no current flows in the glass tube in a normal state even if electrical charge is stored in the capacitor. However, if a high voltage is applied to the trigger electrode to produce an electrical breakdown, electricity stored in the capacitor flows momentarily in the glass tube, and xenon atoms or molecules are excited at this time to cause light emission. Such a xenon flash lamp FL has the property of being capable of emitting extremely intense light as compared with a light source that stays lit continuously such as a halogen lamp because the electrostatic energy previously stored in the capacitor is converted into an ultrashort light pulse ranging from 0.1 to 100 milliseconds. Thus, the flash lamps FL are pulsed light emitting lamps which emit light instantaneously for an extremely short time period of less than one second. The light emission time of the flash lamps FL is adjustable by the coil constant of a lamp light source which supplies power to the flash lamps FL.

The reflector 52 is provided over the plurality of flash lamps FL so as to cover all of the flash lamps FL. A fundamental function of the reflector 52 is to reflect flashes of light emitted from the plurality of flash lamps FL toward the heat treatment space 65. The reflector 52 is a plate made of an aluminum alloy. A surface of the reflector 52 (a surface which faces the flash lamps FL) is roughened by abrasive blasting.

The auxiliary heating part 4 is provided on the opposite side of the chamber 6 from the flash heating part 5, i.e. under the chamber 6. The auxiliary heating part 4 includes the substrate 91 and the chips 45 inside an enclosure 41. Each of the chips 45 in the present preferred embodiment is a VCSEL (Vertical Cavity Surface Emitting Laser) as a semiconductor light emitting element. The auxiliary heating part 4 is an auxiliary light source that directs light from under the chamber 6 through the lower chamber window 64 toward the heat treatment space 65 to heat the semiconductor wafer W by means of the chips 45. For ease of understanding, the substrate 91 and the chips 45 which are principal parts of the auxiliary heating part 4 are shown in simplified form and in exaggeration in FIG. 1.

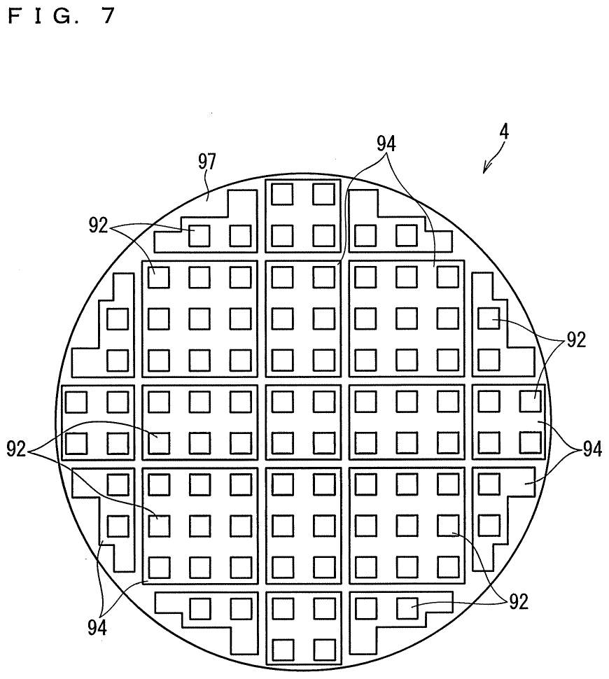

FIG. 7 is a plan view of the inside of the auxiliary heating part 4 as seen from above (from the chamber 6 side). Multiple modules 94 are formed on an upper surface of a base 97. The base 97 is, for example, a disk-shaped member. The base 97 functions as a heat sink for dissipating the heat generated from the chips 45 which emit light, and is made of a metal (e.g., copper) with a high thermal conductivity. A flow channel for circulating cooling water is formed inside the base 97 which is a plate-like member.

The upper surface of the base 97 which is a single disk-shaped member is divided into multiple areas, and the modules 94 are provided in the respective areas. As shown in FIG. 7, the modules 94 have square, rectangular, stepped, and other planar shapes. The combination of the modules 94 having such various shapes substantially covers the entire upper surface of the circular base 97. The auxiliary heating part 4 is supplied with power from a power supply part 49 (FIG. 1), and power control at this time is performed for each of the modules 94. In other words, each of the modules 94 is the smallest control unit. For example, the power control is performed in such a manner that a relatively large amount of power is supplied to the modules 94 opposed to a peripheral portion of the semiconductor wafer W held by the holder 7 whereas a relatively small amount of power is supplied to the modules 94 opposed to a central portion of the semiconductor wafer W.

Each of the modules 94 is provided with multiple chip groups 92. The number of chip groups 92 mounted differs depending on the modules 94, but the chip groups 92 are disposed at a substantially uniform density over the entire upper surface of the base 97. It should be noted that the chip groups 92 need not necessarily be disposed at a uniform density. For example, the chip groups 92 under the peripheral portion of the semiconductor wafer W held by the holder 7 may be disposed at a higher density than the chip groups 92 under the central portion thereof.

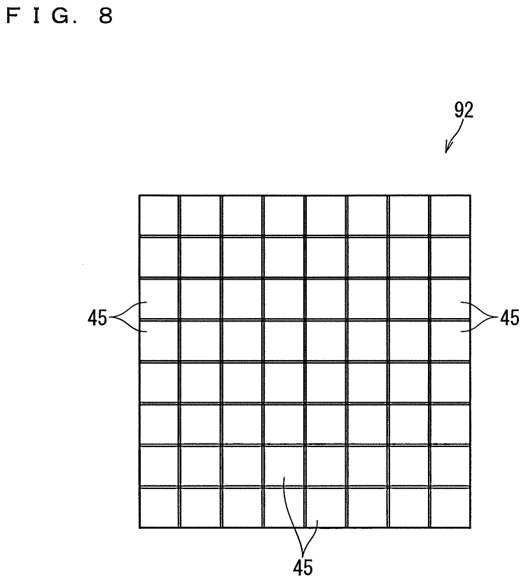

FIG. 8 is a plan view of a chip group 92. One chip group 92 is a group of 64 chips 45 arranged in an 8-by-8 array, for example. The 64 chips 45 included in one chip group 92 are connected in series. Since one chip group 92 includes 64 chips 45, one module 94 is provided with hundreds of chips 45, and the entire auxiliary heating part 4 is provided with thousands of chips 45.

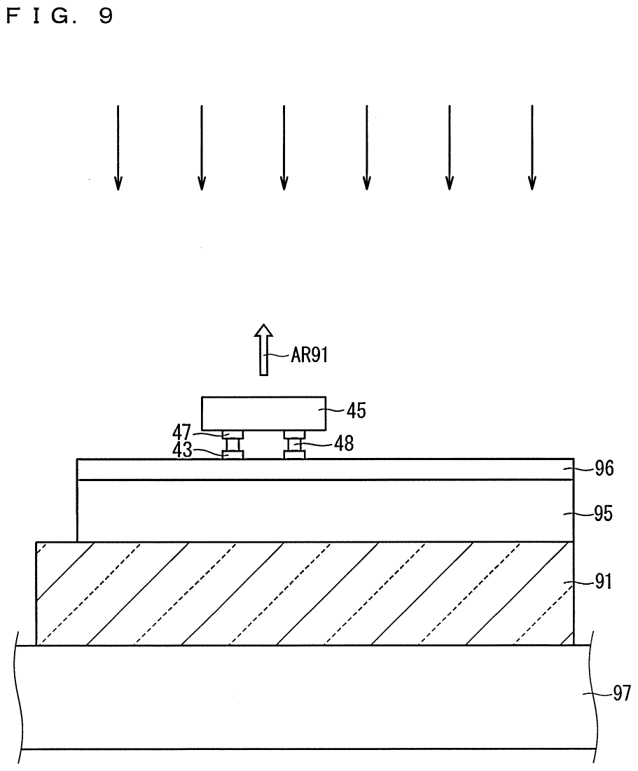

FIG. 9 is a view showing a method for mounting a chip 45. One substrate 91 is provided for each of the modules 94. The substrate 91 is provided on the upper surface of the base 97 which is common to the multiple modules 94. The substrate 91 has plate-like planar shapes similar to those of the modules 94 shown in FIG. 7. In the present preferred embodiment, the substrate 91 is an insulative substrate made of an inorganic insulating material. The substrate 91 is made of, for example, aluminum nitride (AlN) which is an inorganic insulating material. Aluminum nitride has a high thermal conductivity and high electrical insulation properties among ceramics.

A pattern 95 of an electrically conductive material (e.g., copper (Cu)) is formed on an upper surface of the substrate 91. The pattern 95 constitutes a circuit which supplies power to the chips 45 in each of the modules 94. The pattern 95 is formed, for example, using a photolithographic technique. Copper has high electrical conductivity after silver, and is less expensive than gold and silver.

A plating layer 96 of gold (Au) is formed on the upper side of the pattern 95. Gold plating prevents the oxidation of the pattern 95 of copper and has excellent solderability. Gold also has high electrical conductivity.

The chip 45 is connected through the plating layer 96 of gold to the pattern 95. The chip 45 is a VCSEL (Vertical Cavity Surface Emitting Laser) as a single semiconductor light emitting element. The VCSEL is a kind of semiconductor laser, and emits light in a direction perpendicular to a surface of a semiconductor substrate. The VCSEL is capable of emitting light of a relatively high intensity, and emits light of high directivity.

In the present preferred embodiment, the chip 45 is attached using a flip chip mounting method. The flip chip mounting method refers to a mounting method in which the chip 45 is flipped vertically so that a connection surface of the chip 45 faces downward and is connected to electrodes on the pattern side through protruding terminals (bumps). In general, the connection surface of a chip faces upward, and electrodes provided on the upper surface thereof are connected to the electrodes on the pattern side by wires (wire bonding mounting method). In the present preferred embodiment, on the other hand, the connection surface of the chip 45 faces downward, and electrodes 47 provided on the lower surface thereof are connected to electrodes 43 on the pattern side provided on the plating layer 96 by bumps 48. Thus, the bumps 48 which are connection portions between the chip 45 and the pattern 95 are located under the chip 45. The bumps 48 are made of gold, for example. A protective film may be formed on part of the plating layer 96 to which the chip 45 is not attached.

When power is supplied from the power supply part 49 through the pattern 95 to the chip 45, light is emitted from the chip 45 which is the VCSEL in an upward direction as indicated by an arrow AR91. When light is emitted from the multiple chips 45 provided in the auxiliary heating part 4, the entire lower surface of the semiconductor wafer W held by the holder 7 in the chamber 6 is irradiated with the light.

The controller 3 controls the aforementioned various operating mechanisms provided in the heat treatment apparatus 1. The controller 3 is similar in hardware configuration to a typical computer. Specifically, the controller 3 includes a CPU that is a circuit for performing various computation processes, a ROM or read-only memory for storing a basic program therein, a RAM or readable/writable memory for storing various pieces of information therein, and a storage part (e.g., a magnetic disk or an SSD) for storing control software, data and the like thereon. The CPU in the controller 3 executes a predetermined processing program, whereby the processes in the heat treatment apparatus 1 proceed.

The heat treatment apparatus 1 further includes, in addition to the aforementioned components, various cooling structures to prevent an excessive temperature rise in the auxiliary heating part 4, the flash heating part 5, and the chamber 6 because of the heat energy generated from the chips 45 and the flash lamps FL during the heat treatment of a semiconductor wafer W. As an example, a water cooling tube (not shown) is provided in the walls of the chamber 6. Also, the auxiliary heating part 4 and the flash heating part 5 have an air cooling structure for forming a gas flow therein to exhaust heat. Air is supplied to a gap between the upper chamber window 63 and the lamp light radiation window 53 to cool down the flash heating part 5 and the upper chamber window 63.

Next, a treatment operation in the heat treatment apparatus 1 will be described. A typical heat treatment operation for an ordinary semiconductor wafer (product wafer) W that becomes a product will be described. The semiconductor wafer W to be treated is implanted with impurities by an ion implantation method. The activation of the impurities is performed by an annealing process in the heat treatment apparatus 1. A procedure for the treatment of the semiconductor wafer W which will be described below proceeds under the control of the controller 3 over the operating mechanisms of the heat treatment apparatus 1.

Prior to the treatment of the semiconductor wafer W, the valve 84 for supply of gas is opened, and the valve 89 for exhaust of gas is opened, so that the supply and exhaust of gas into and out of the chamber 6 start. When the valve 84 is opened, nitrogen gas is supplied through the gas supply opening 81 into the heat treatment space 65. When the valve 89 is opened, the gas within the chamber 6 is exhausted through the gas exhaust opening 86. This causes the nitrogen gas supplied from an upper portion of the heat treatment space 65 in the chamber 6 to flow downwardly and then to be exhausted from a lower portion of the heat treatment space 65.

Subsequently, the gate valve 185 is opened to open the transport opening 66. A transport robot outside the heat treatment apparatus 1 transports a semiconductor wafer W to be treated through the transport opening 66 into the heat treatment space 65 of the chamber 6. At this time, there is a danger that an atmosphere outside the heat treatment apparatus 1 is carried into the heat treatment space 65 as the semiconductor wafer W is transported into the heat treatment space 65. However, the nitrogen gas is continuously supplied into the chamber 6. Thus, the nitrogen gas flows outwardly through the transport opening 66 to minimize the outside atmosphere carried into the heat treatment space 65.

The semiconductor wafer W transported into the heat treatment space 65 by the transport robot is moved forward to a position lying immediately over the holder 7 and is stopped thereat. Then, the pair of transfer arms 11 of the transfer mechanism 10 is moved horizontally from the retracted position to the transfer operation position and is then moved upwardly, whereby the lift pins 12 pass through the through holes 79 and protrude from the upper surface of the holding plate 75 of the susceptor 74 to receive the semiconductor wafer W. At this time, the lift pins 12 move upwardly to above the upper ends of the substrate support pins 77.

After the semiconductor wafer W is placed on the lift pins 12, the transport robot moves out of the heat treatment space 65, and the gate valve 185 closes the transport opening 66. Then, the pair of transfer arms 11 moves downwardly to transfer the semiconductor wafer W from the transfer mechanism 10 to the susceptor 74 of the holder 7, so that the semiconductor wafer W is held in a horizontal attitude from below. The semiconductor wafer W is supported by the substrate support pins 77 provided upright on the holding plate 75, and is held by the susceptor 74. The semiconductor wafer W is held by the holder 7 in such an attitude that the front surface thereof that is implanted with impurities is the upper surface. A predetermined distance is defined between a back surface (a main surface opposite from the front surface) of the semiconductor wafer W supported by the substrate support pins 77 and the holding surface 75a of the holding plate 75. The pair of transfer arms 11 moved downwardly below the susceptor 74 is moved back to the retracted position, i.e. to the inside of the recessed portion 62, by the horizontal movement mechanism 13.

After the semiconductor wafer W is held from below in a horizontal attitude by the susceptor 74 of the holder 7 made of quartz, light is directed from the auxiliary heating part 4 onto the semiconductor wafer W to start preheating (or assist-heating). When power is supplied from the power supply part 49 to the auxiliary heating part 4, light is emitted from the multiple chips 45. The light emitted from the chips 45 which are VCSELs is transmitted through the lower chamber window 64 and the susceptor 74 both made of quartz, and impinges upon the entire lower surface of the semiconductor wafer W.

The chips 45 which are VCSELs that emit light also generate heat, but this heat is dissipated by conduction from the substrate 91 to the base 97 being cooled. Since the substrate 91 is made of aluminum nitride which has a high thermal conductivity, the heat generated from the chips 45 is smoothly released to the base 97. This suppresses excessive temperature rise in the chips 45.

By receiving light irradiation from the multiple chips 45, the semiconductor wafer W is preheated, so that the temperature of the semiconductor wafer W increases. The temperature of the semiconductor wafer W which is on the increase by the irradiation with light from the auxiliary heating part 4 is measured by the radiation thermometer 20.

The measured temperature of the semiconductor wafer W is transmitted to the controller 3. The controller 3 controls the outputs from the chips 45 while monitoring whether the temperature of the semiconductor wafer W which is on the increase by the irradiation with light from the auxiliary heating part 4 reaches a predetermined preheating temperature T1 or not. In other words, the controller 3 effects feedback control of the outputs from the chips 45 which are VCSELs in units of the modules 94 so that the temperature of the semiconductor wafer W is equal to the preheating temperature T1, based on the value measured by the radiation thermometer 20. The preheating temperature T1 shall be on the order of 200° to 800° C., preferably on the order of 350° to 600° C., (in the present preferred embodiment, 600° C.) at which there is no apprehension that the impurities implanted in the semiconductor wafer W are diffused by heat.

After the temperature of the semiconductor wafer W reaches the preheating temperature T1, the controller 3 maintains the temperature of the semiconductor wafer W at the preheating temperature T1 for a short time. Specifically, at the point in time when the temperature of the semiconductor wafer W measured by the radiation thermometer 20 reaches the preheating temperature T1, the controller 3 adjusts the outputs from the chips 45 in units of the modules 94 to maintain the temperature of the semiconductor wafer W at approximately the preheating temperature T1.

The flash lamps FL in the flash heating part 5 irradiate the front surface of the semiconductor wafer W held by the susceptor 74 with a flash of light at the point in time when a predetermined time period has elapsed since the temperature of the semiconductor wafer W reached the preheating temperature T1. At this time, part of the flash of light emitted from the flash lamps FL travels directly toward the interior of the chamber 6. The remainder of the flash of light is reflected once from the reflector 52, and then travels toward the interior of the chamber 6. The irradiation of the semiconductor wafer W with such flashes of light achieves the flash heating of the semiconductor wafer W.

The flash heating, which is achieved by the emission of a flash of light from the flash lamps FL, is capable of increasing the front surface temperature of the semiconductor wafer W in a short time. Specifically, the flash of light emitted from the flash lamps FL is an intense flash of light emitted for an extremely short period of time ranging from about 0.1 to about 100 milliseconds as a result of the conversion of the electrostatic energy previously stored in the capacitor into such an ultrashort light pulse. The front surface temperature of the semiconductor wafer W subjected to the flash heating by the flash irradiation from the flash lamps FL momentarily increases to a treatment temperature T2 of 1000° C. or higher. After the impurities implanted in the semiconductor wafer W are activated, the temperature of the front surface of the semiconductor wafer W decreases rapidly. Because of the capability of increasing and decreasing the temperature of the front surface of the semiconductor wafer W in an extremely short time, the heat treatment apparatus 1 achieves the activation of the impurities implanted in the semiconductor wafer W while suppressing the diffusion of the impurities due to heat. It should be noted that the time required for the activation of the impurities is extremely short as compared with the time required for the thermal diffusion of the impurities. Thus, the activation is completed in a short time ranging from about 0.1 to about 100 milliseconds during which no diffusion occurs.

After a predetermined time period has elapsed since the completion of the flash heating treatment, the irradiation with the light from the auxiliary heating part 4 also stops. This causes the temperature of the semiconductor wafer W to decrease rapidly from the preheating temperature T1. The radiation thermometer 20 measures the temperature of the semiconductor wafer W which is on the decrease. The result of measurement is transmitted to the controller 3. The controller 3 monitors whether the temperature of the semiconductor wafer W is decreased to a predetermined temperature or not, based on the result of measurement by means of the radiation thermometer 20. After the temperature of the semiconductor wafer W is decreased to the predetermined temperature or below, the pair of transfer arms 11 of the transfer mechanism 10 is moved horizontally again from the retracted position to the transfer operation position and is then moved upwardly, so that the lift pins 12 protrude from the upper surface of the susceptor 74 to receive the heat-treated semiconductor wafer W from the susceptor 74. Subsequently, the transport opening 66 which has been closed is opened by the gate valve 185, and the transport robot outside the heat treatment apparatus 1 transports the semiconductor wafer W placed on the lift pins 12 out of the chamber 6. Thus, the heating treatment of the semiconductor wafer W is completed.

The auxiliary heating part 4 is provided in opposed relation to the flash heating part 5, with the chamber 6 therebetween. Thus, when the flash lamps FL emit flashes of light, there are cases in which the direct flashes of light or the reflected flashes of light which are reflected from the inner wall of the chamber 6 reach the auxiliary heating part 4 to impinge upon the substrate 91. In particular, when the flash lamps FL emit flashes of light during maintenance, the flashes of light easily reach the substrate 91 because the semiconductor wafer W is not held by the susceptor 74.

In the mounting of the chips 45 on the substrate 91 in the present preferred embodiment, the connection surface of each of the chips 45 faces downward, and the electrodes 47 provided on the lower surface thereof are connected to the electrodes 43 on the pattern 95 side by the bumps 48. In other words, the flip chip mounting method is used. The flash lamps FL are provided on the upper side of the chamber 6, i.e. over the auxiliary heating part 4. Thus, the electrodes 47 provided on the lower surface (a second surface) of each chip 45 opposite from the upper surface (a first surface) thereof opposed to the flash lamps FL are connected to the electrodes 43 of the substrate 91 through the bumps 48.

When the chips 45 are mounted by the wire bonding mounting method as in a conventional manner, there is a danger that the wires are exposed to flashes of light emitted from the flash lamps FL to break. When the electrodes 47 provided on the second surface of each chip 45 opposite from the first surface thereof opposed to the flash lamps FL are connected to the electrodes 43 of the substrate 91 through the bumps 48 as in the present preferred embodiment, the bumps 48 are hidden behind the chips 45 as seen from the flash lamps FL, and are not exposed to the flashes of light (with reference to FIG. 9). As a result, the bumps 48 which are the connection portions between each chip 45 and the substrate 91 are prevented from being damaged by the flash irradiation. This prevents damages to the auxiliary heating part 4 due to the flash irradiation.

In the present preferred embodiment, the substrate 91 is made of aluminum nitride (AlN) which is an inorganic insulating material. In the conventional techniques, the substrate is made of copper or the like with good thermal conductivity. Since a copper pattern cannot be formed directly on such an electrically conductive substrate, an insulative layer made of epoxy resin or the like is sandwiched therebetween to form the pattern. In this case, the insulative layer is exposed to flashes of light during the flash irradiation to get burned in some cases. The formation of the substrate 91 made of an inorganic insulating material as in the present preferred embodiment eliminates the need to provide the insulative layer. Thus, if the substrate 91 is exposed to flashes of light during the flash irradiation, the substrate 91 will not get burned. This prevents damages to the auxiliary heating part 4 due to the flash irradiation.

In particular, aluminum nitride has a high thermal conductivity among ceramics, so that the heat generated in the chips 45 is smoothly conducted from the substrate 91 to the base 97. In other words, the substrate 91 made of aluminum nitride is not only resistant to the flash irradiation but also excellent as a heat sink.

While the preferred embodiment according to the present invention has been described hereinabove, various modifications of the present invention in addition to those described above may be made without departing from the scope and spirit of the invention. For example, the flip chip mounting method is used to mount the chips 45 on the substrate 91 made of an inorganic insulating material in the aforementioned preferred embodiment. The present invention, however, is not limited to this. The wire bonding mounting method may be used to mount the chips 45 on the substrate 91 made of an inorganic insulating material. This also eliminates the need to provide the insulative layer if the substrate 91 made of an inorganic insulating material is used, thereby preventing the insulative layer from getting burned by the flash irradiation.

Alternatively, the flip chip mounting method may be used to mount the chips 45 on an electrically conductive substrate. Even in this case, the bumps 48 are no longer exposed to flashes of light, whereby the breaks due to the flash irradiation are prevented.

The substrate 91 is made of aluminum nitride in the aforementioned preferred embodiment. The present invention, however, is not limited to this. The substrate 91 may be made of other inorganic insulating materials. For example, the substrate 91 may be made of silicon carbide (SiC), quartz glass (SiO₂), or aluminum oxide (Al₂O₃). The formation of the substrate 91 made of one inorganic insulating material selected from the group consisting of aluminum nitride, silicon carbide, quartz glass, and aluminum oxide eliminates the need to provide the insulative layer, thereby preventing the insulative layer from getting burned by the flash irradiation. However, the substrate 91 is preferably made of aluminum nitride which has a high thermal conductivity when heat dissipation from the chips 45 is taken into consideration.

In the aforementioned embodiment, the semiconductor light emitting element constituting each chip 45 is the VCSEL. The present invention, however, is not limited to this. The chips 45 may be other semiconductor light emitting elements. For example, an LED (Light Emitting Diode) or an LD (Laser Diode) as the semiconductor light emitting element may be used for the chips 45. Regardless of the type of semiconductor light emitting element, the chips 45 are mounted in the same manner as in the aforementioned preferred embodiment.

Also, multiple types of semiconductor light emitting elements may be provided in the single auxiliary heating part 4. For example, VCSELs and laser diodes may be provided in the single auxiliary heating part 4 in such a manner that the entire surface of the semiconductor wafer W is irradiated with light from the laser diodes whereas the peripheral portion of the semiconductor wafer W where the temperature decrease is liable to occur is irradiated with light of high directivity from the VCSELs.

Although the 30 flash lamps FL are provided in the flash heating part 5 in the aforementioned preferred embodiment, the present invention is not limited to this. Any number of flash lamps FL may be provided. The flash lamps FL are not limited to the xenon flash lamps, but may be krypton flash lamps.

While the invention has been shown and described in detail, the foregoing description is in all aspects illustrative and not restrictive. It is therefore understood that numerous modifications and variations can be devised without departing from the scope of the invention.

What is claimed is:

1. A heat treatment apparatus for irradiating a semiconductor wafer with light to heat the semiconductor wafer, comprising:
a chamber for receiving a semiconductor wafer therein;
a holder for holding said semiconductor wafer in said chamber;
an auxiliary light source provided on one side of said chamber and for irradiating said semiconductor wafer held by said holder with light, said auxiliary light source including a substrate and a chip including a semiconductor light emitting element; and
a flash lamp provided on the other side of said chamber and for irradiating said semiconductor wafer preheated by said auxiliary light source with a flash of light,
wherein an electrode provided on a second surface of said chip opposite from a first surface thereof opposed to said flash lamp is connected to said substrate through a bump.

2. The heat treatment apparatus according to claim 1,
wherein said substrate is made of an inorganic insulating material.

3. The heat treatment apparatus according to claim 2,
wherein said substrate is made of a material selected from the group consisting of aluminum nitride, silicon carbide, quartz glass, and aluminum oxide.

4. The heat treatment apparatus according to claim 2,
wherein said chip is connected to a pattern of an electrically conductive material provided on said substrate.

5. The heat treatment apparatus according to claim 1,
wherein said semiconductor light emitting element is one selected from the group consisting of a light emitting diode, a laser diode, and a vertical cavity surface emitting laser.

6. A heat treatment apparatus for irradiating a semiconductor wafer with light to heat the semiconductor wafer, comprising:
a chamber for receiving a semiconductor wafer therein;
a holder for holding said semiconductor wafer in said chamber;
an auxiliary light source provided on one side of said chamber and for irradiating said semiconductor wafer held by said holder with light, said auxiliary light source including an insulative substrate made of an inorganic material and a chip including a semiconductor light emitting element; and
a flash lamp provided on the other side of said chamber and for irradiating said semiconductor wafer preheated by said auxiliary light source with a flash of light.

7. The heat treatment apparatus according to claim 6,
wherein said insulative substrate is made of a material selected from the group consisting of aluminum nitride, silicon carbide, quartz glass, and aluminum oxide.

8. The heat treatment apparatus according to claim 6,
wherein said chip is connected to a pattern of an electrically conductive material provided on said insulative substrate.

9. The heat treatment apparatus according to claim 6,
wherein said semiconductor light emitting element is one selected from the group consisting of a light emitting diode, a laser diode, and a vertical cavity surface emitting laser.
